(19) United States
(12) Patent Application Publication
(10) Pub. No.: US 2011/0099459 A1
(43) Pub. Date: Apr. 28, 2011

(54) SEMICONDUCTOR MEMORY DEVICE

(75) Inventors: Toshihiro NAKAMURA, Kyoto (JP); Masahisa IIda, Osaka (JP)

(73) Assignee: PANASONIC CORPORATION, Osaka (JP)

(21) Appl. No.: 12/979,952

(22) Filed: Dec. 28, 2010

Related U.S. Application Data
(63) Continuation of application No. PCT/JP2009/000263, filed on Jan. 23, 2009.

(30) Foreign Application Priority Data
Jul. 10, 2008 (JP) 2008-180388

(51) Int. Cl. H03M 13/05; G06F 11/10

(52) U.S. Cl. 714/763; 714/E11.034

(57) ABSTRACT

A semiconductor memory device includes a memory array, an error correction code circuit, and a timing control signal generator configured to, based on a first timing control signal used to control a timing at which data to be input to the error correction code circuit is transferred to the error correction code circuit, generate a second timing control signal used to control a timing at which data output from the error correction code circuit is transferred to another circuit. The timing control signal generator includes a circuit which is the same as or corresponds to at least a portion of the error correction code circuit, and is configured to delay a timing of the first timing control signal by a period of time corresponding to a delay time of the error correction code circuit, and output the second timing control signal, depending on the delayed timing.

### CROSS-REFERENCE TO RELATED APPLICATIONS

This is a continuation of PCT International Application PCT/JP2009/000263 filed on Jan. 23, 2009, which claims priority to Japanese Patent Application No. 2008-180388 filed on Jul. 10, 2008. The disclosures of these applications including the specifications, the drawings, and the claims are hereby incorporated by reference in their entirety.

### BACKGROUND

The present disclosure relates to semiconductor memory devices, and more particularly, to semiconductor memory devices including an error correction code (ECC) circuit.

In recent years, as semiconductor fabrication technologies have been advanced to provide devices using finer and finer design rules, the integration densities of memories, such as a dynamic random access memory (hereinafter referred to as a DRAM) and a static random access memory (hereinafter referred to as an SRAM), have been increased.

A technique known as “redundancy replacement” has been developed to improve the yield of DRAM or SRAM chips. In the technique, a defective memory cell is replaced with a spare memory cell. The redundancy replacement technique, however, may not repair defects occurring due to a degradation in device characteristics during use or defects occurring due to soft errors induced by alpha rays, cosmic rays, or the like. This problem arises in devices, such as memory cells, sense amplifiers, and the like, having finer design rules. Such a reliability problem may be solved by a known self-correction technique using the ECC circuit technique.

Although a system has been traditionally built on a plurality of chips, advances in microfabrication technology have increased the integration density to allow integration of a memory, such as a DRAM, an SRAM, or the like, and a logic circuit or a CPU into a single chip. Such a chip is called a system-on-chip (SOC). There is an increasing demand for SOC chips. A feature of SOC chips is that the width of a bus for a memory integrated into the chip can be relatively arbitrarily set, and therefore, a considerably wide bus configuration (e.g., a 256-bit width) can be used for a general single memory. The use of such a wide-width bus configuration improves the rate of data transfer between the CPU and the memory, resulting in a significant improvement in performance.

A known semiconductor memory device having the ECC function is described in, for example, Japanese Patent Publication No. 2006-4476. The semiconductor memory device includes a memory cell array including a large number of memory cells arranged in an array, dummy bit lines having the same line width and line pitch as those of bit lines in the memory cell array, dummy word lines having the same line width and line pitch as those of word lines in the memory cell array, a buffer circuit configured to write data to the memory cells, and a dummy write buffer circuit configured to drive the dummy bit lines. These elements are used to achieve memory operation with appropriate timing which is determined, depending on the capacity configuration (configuration of words×bits) of the memory or the like.

FIG. 10 is a block diagram schematically showing a configuration of a conventional semiconductor memory device including an ECC circuit, where the semiconductor memory device is a DRAM.

As a representative operation of the DRAM memory including the ECC circuit, read-modify-write operation will be described hereinafter with reference to FIG. 10.

In FIG. 10, the conventional semiconductor memory device includes a memory array 1000, a read latch circuit 1001, an ECC circuit 1002, a data latch/input/output circuit 1003, a write buffer circuit 1004, and a delay circuit 1005. The memory array 1000 includes a normal memory array 1000a and a parity memory array 1000b. The ECC circuit 1002 includes a syndrome generation circuit 1002a, an error detection circuit 1002b, an error correction circuit 1002c, and a parity generation circuit 1002d.

Normal data and parity data read from the normal memory array 1000a and the parity memory array 1000b, respectively, are input via the read latch circuit 1001 to the syndrome generation circuit 1002a and then ECC processes, i.e., syndrome generation by the syndrome generation circuit 1002a and error detection by the error detection circuit 1002b are performed. The resultant data is subjected to error correction by the error correction circuit 1002c in the succeeding stage before being output via the data latch/input/output circuit 1003 to the outside of the memory. Data input to the data latch/input/output circuit 1003 is rewritten using data DI<127:0> input from the outside of the DRAM before being input to the parity generation circuit 1002d, which then generates parity data. The normal data and the parity data are written via the write buffer circuit 1004 to the normal memory array 1000a and the parity memory array 1000b, respectively. A write signal WYPA which is used to control the write buffer circuit 104 when data is written to the normal memory array 1000a and the parity memory array 1000b, is appropriately delayed via the delay circuit 1005, such as a transistor circuit or the like, based on a read signal RYPA which is used to control the read latch circuit 1001 when data is read from the normal memory array 1000a and the parity memory array 1000b, before being input to the write buffer circuit 1004.

### SUMMARY

The aforementioned conventional semiconductor memory device including an ECC circuit performs a series of ECC processes, such as syndrome generation, syndrome decoding, error correction, and parity generation, based on normal data and parity data stored in the memory array 1000, and writes the normal data and the parity data to the memory array 1000 based on externally input data as well as the normal data and the parity data. Therefore, compared to a semiconductor memory device without an ECC circuit, the period of time which it takes to perform the ECC processes is required, and therefore, a reduction in memory operation performance is significantly affected.

The ECC circuit which is included in the semiconductor memory device inherently has a feature that the aspect ratio of the block in the layout is large, and therefore, the length of an interconnection between each element is large on signal paths of the ECC processes in the ECC circuit block. As described above, the recent advance in device microfabrication technology has been accompanied by a tendency toward higher and higher interconnection resistance. Therefore, in the series of ECC processes from syndrome generation to parity generation, there is a large interconnection delay due to interconnection resistance, parasitic capacitance between interconnections, and the like in addition to a transistor delay in circuit devices. The write signal which is used to write normal data and parity data to the memory array needs to become active after the series of ECC processes from syndrome generation to parity generation are completed. As described above, however, the signal paths in the ECC processes contain a plurality of delays, such as a transistor delay, a signal interconnection delay, and the like. Because the delays vary separately due to various factors, such as temperature, voltage, and the like, the amount of the signal delay varies significantly.

Therefore, for a timing at which the write signal transitions active, in order to reduce or prevent erroneous operation, a sufficient delay amount needs to be ensured in addition to the ECC process time, taking the above variations into consideration.

Therefore, although the semiconductor memory device including the ECC circuit needs to not only reduce the increase in the period of time required for the ECC processes, but also improve memory operating speed performance, it is difficult to reduce the margin of the period of time from the ECC processes to the write signal active timing, resulting in a barrier to improvement of the overall speed performance of the semiconductor memory device.

According to Japanese Patent Publication No. 2006-4476, dummy cells are provided in the memory array and are used as a dummy circuit for controlling the operating timing of a memory core, whereby the timings of operations in the memory core, such as activation of a sense amplifier and the like, can be appropriately regulated to improve the memory operating speed performance. As described above, however, in the semiconductor memory device including the ECC circuit, not only a period of time which it takes to perform operations in the memory core, such as the sense amplifier activation and the like (described in Japanese Patent Publication No. 2006-4476), but also a period of time which it takes to perform the ECC processes in the ECC circuit, the peripheral circuits, and the input/output circuit are required, and the period of time required for the ECC processes has a significant influence on the operational performance of the memory core. Japanese Patent Publication No. 2006-4476 does not mention improvement of the speed performance of operation from the ECC processes in the ECC circuit, which is often provided in the peripheral circuit or around the input/output circuit, to data write, or any technique thereof. For the operation from the ECC processes to data write, the improvement of the memory operating speed performance remains yet to be achieved.

The present disclosure has been made in view of the above problems. Detailed description describes implementations of a semiconductor memory device including an ECC circuit in which the memory operating speed performance is improved by optimizing timings of an ECC process, data write to a memory cell, and the like.

An example semiconductor memory device includes a memory array including a normal memory array configured to store normal data and a code memory array configured to store error detection/correction code data used to perform error detection/correction with respect to the normal data, an error correction code circuit including a code generator configured to generate the error detection/correction code data based on the normal data to be written to the normal memory array, and an error detector/corrector configured to, based on the normal data and the error detection/correction code data read out from the memory array, perform error detection/correction with respect to the normal data, and a timing control signal generator configured to, based on a first timing control signal used to control a timing at which data to be input to the error correction code circuit is transferred to the error correction code circuit, generate a second timing control signal used to control a timing at which data output from the error correction code circuit is transferred from the error correction code circuit to another circuit. The timing control signal generator includes a circuit which is the same as or corresponds to at least a portion of the error correction code circuit, and is configured to delay a timing of the first timing control signal by a period of time corresponding to a delay time of the error correction code circuit, and output the second timing control signal, depending on the delayed timing of the first timing control signal.

In the example semiconductor memory device, modified normal data including at least a portion of data which has been subjected to the error detection/correction by the error detector/corrector based on the normal data and the error detection/correction code data read out from the memory array, and at least a portion of data which has been input from the outside of the semiconductor memory device, and error detection/correction code data generated by the code generator based on the second normal data, may be written to the memory array. The first timing control signal may be a signal used to control a timing at which the normal data and the error detection/correction code data read out from the memory array are transferred to the error detector/corrector. The second timing control signal may be a signal used to control a timing at which the modified normal data and the error detection/correction code data to be written to the memory array is transferred to the memory array. The timing control signal generator may include a circuit which is the same as or corresponds to at least a portion of a circuit or circuits constituting the error detector/corrector and the code generator, and may be configured to delay a timing of the first timing control signal by a period of time corresponding to a delay time of the error detector/corrector and the code generator, and output the second timing control signal, depending on the delayed timing of the first timing control signal.

In the example semiconductor memory device, the first timing control signal may be a signal used to control a timing at which the normal data and the error detection/correction code data read out from the memory array are transferred to the error detector/corrector. The second timing control signal may be a signal used to control a timing at which data subjected to the error detection/correction by the error detector/corrector is transferred to a circuit external to the semiconductor memory device. The timing control signal generator may include a circuit which is the same as or corresponds to at least a portion of a circuit or circuits constituting the error detector/corrector, and may be configured to delay a timing of the first timing control signal by a period of time corresponding to a delay time of the error detector/corrector, and output the second timing control signal, depending on the delayed timing of the first timing control signal.

In the example semiconductor memory device, the first timing control signal may be a signal used to control a timing at which the normal data which has been input from the outside of the semiconductor memory device and is to be written to the memory array is transferred to the code generator. The second timing control signal may be a signal used to control a timing at which the normal data to be written to the memory array, and the error detection/correction code data generated by the code generator based on the normal data, are transferred to the memory array. The timing control signal generator may include a circuit which is the same as or corresponds to at least a portion of a circuit or circuits constituting the code generator, and may be configured to delay a timing of the first timing control signal by a period of time corresponding to a delay time of the code generator, and output the second timing control signal, depending on the delayed timing of the first timing control signal.

Therefore, the second timing control signal used to control, for example, a timing at which write data is transferred to the memory array is generated, depending on the delay time of the error detector/corrector or the like, whereby the margin of timing control can be easily set to be small.

In the example semiconductor memory device, the timing control signal generator may include, on a signal path between the first and second timing control signals, the same number of stages of transistors as the number of stages of transistors provided between an input signal and an output signal of the error correction code circuit.

In the example semiconductor memory device, the timing control signal generator may include, on a signal path between the first and second timing control signals, a logic element corresponding to a logic element provided between an input signal and an output signal of the error correction code circuit.

In the example semiconductor memory device, the logic element may include a logic element configured to receive an input signal to be passed and one or more other signals, and the one or more other signals may be maintained at a level which allows an output of the logic element to transition, depending on level transition of the input signal to be passed.

In the example semiconductor memory device, the number of toggles of transistors provided on a signal path between the first and second timing control signals in the timing control signal generator may be the same as the number of toggles of transistors provided between an input signal and an output signal of the error correction code circuit.

In the example semiconductor memory device, in the timing control signal generator, all transistor or transistors provided on a signal path between the first and second timing control signals may be toggled, depending on level transition of the first timing control signal.

In the example semiconductor memory device, the error correction code circuit and the timing control signal generator may be configured to have an equal sum of a transistor delay caused by a signal passing through a transistor or transistors and an interconnection delay caused by interconnection parasitic resistance, and parasitic capacitance between interconnections, of a signal interconnection.

In the example semiconductor memory device, the timing control signal generator may include, on a signal path between the first and second timing control signals, a signal interconnection having a layout corresponding to a signal interconnection between an input signal and an output signal of the error correction code circuit.

In the example semiconductor memory device, the timing control signal generator may include, on a signal path between the first and second timing control signals, a signal interconnection extending back and forth in at least one of two orthogonal directions of an interconnection pattern constituting a signal path from a position of a circuit arrangement of the error correction code circuit where the normal data read out from the memory array, or the normal data which has been input from the outside of the semiconductor memory device and is to be written to the memory array, is input, to a position of the circuit arrangement where data which has been subjected to the error detection/correction, or the error detection/correction code data, is output.

In the example semiconductor memory device, data bits input to or output from the memory array may be divided into a plurality of groups, the timing control signal generator may be provided for each of the groups, and a data transfer timing corresponding to each of the groups may be controlled based on the second timing control signal generated by the corresponding timing control signal generator.

In the example semiconductor memory device, the timing control signal generator may include a plurality of basic timing control signal generators each including a circuit which is the same as or corresponds to at least a portion of a circuit or circuits constituting the error correction code circuit, and configured to delay a timing of the first timing control signal by a period of time corresponding to a delay time of the error correction code circuit, and generate a third timing control signal, depending on the delayed timing of the first timing control signal. Of the plurality of third timing control signals output from the plurality of basic timing control signal generators, one corresponding to a predetermined timing is output as the second timing control signal.

In the example semiconductor memory device, of the plurality of third timing control signals, one corresponding to a most delayed timing may be output as the second timing control signal.

Therefore, the accuracy of timing control can be easily increased.

In the example semiconductor memory device, the timing control signal generator may be formed in a first region in which at least one of an input/output circuit unit configured to control input/output of data between the error correction code circuit and the outside of the semiconductor memory device, and a peripheral logic circuit unit configured to generate a control signal for each unit of the semiconductor memory device, or in a second region adjacent to the first region.

Therefore, the margin of timing control can be easily set to be small as described above, and the circuit area can be reduced, for example.

In the example semiconductor memory device, at least a portion of an interconnection or interconnections constituting the error correction code circuit and at least a portion of an interconnection or interconnections constituting the timing control signal generator may be provided with one or more other interconnections being interposed therebetween.

Therefore, an influence of noise on each signal can be easily reduced.

According to the present disclosure, the decrease in the operating speed performance caused by the incorporation of the ECC function can be reduced.

### BRIEF DESCRIPTION OF THE DRAWINGS

FIG. 1 is a block diagram schematically showing a configuration of a semiconductor memory device according to a first embodiment of the present disclosure.

FIG. 2 is a block diagram schematically showing a configuration of a semiconductor memory device according to a second embodiment of the present disclosure.

FIG. 3 is a circuit diagram showing a detailed configuration of a syndrome generation circuit in a semiconductor memory device according to a third embodiment of the present disclosure.

FIG. 4 is a circuit diagram showing a detailed configuration of a portion of a dummy circuit in the semiconductor memory device of the third embodiment of the present disclosure.

FIG. 5 is a block diagram schematically showing a layout of a semiconductor memory device according to a fourth embodiment of the present disclosure.

FIG. 6 is a layout diagram schematically showing a layout of a semiconductor memory device according to a fifth embodiment of the present disclosure.

FIG. 7 is a layout diagram schematically showing a layout of a semiconductor memory device according to a sixth embodiment of the present disclosure.

FIG. 8 is a layout diagram schematically showing a layout of a semiconductor memory device according to a seventh embodiment of the present disclosure.

FIG. 9 is a layout diagram schematically showing a layout of a semiconductor memory device according to an eighth embodiment of the present disclosure.

FIG. 10 is a block diagram showing a configuration of a conventional semiconductor memory device.

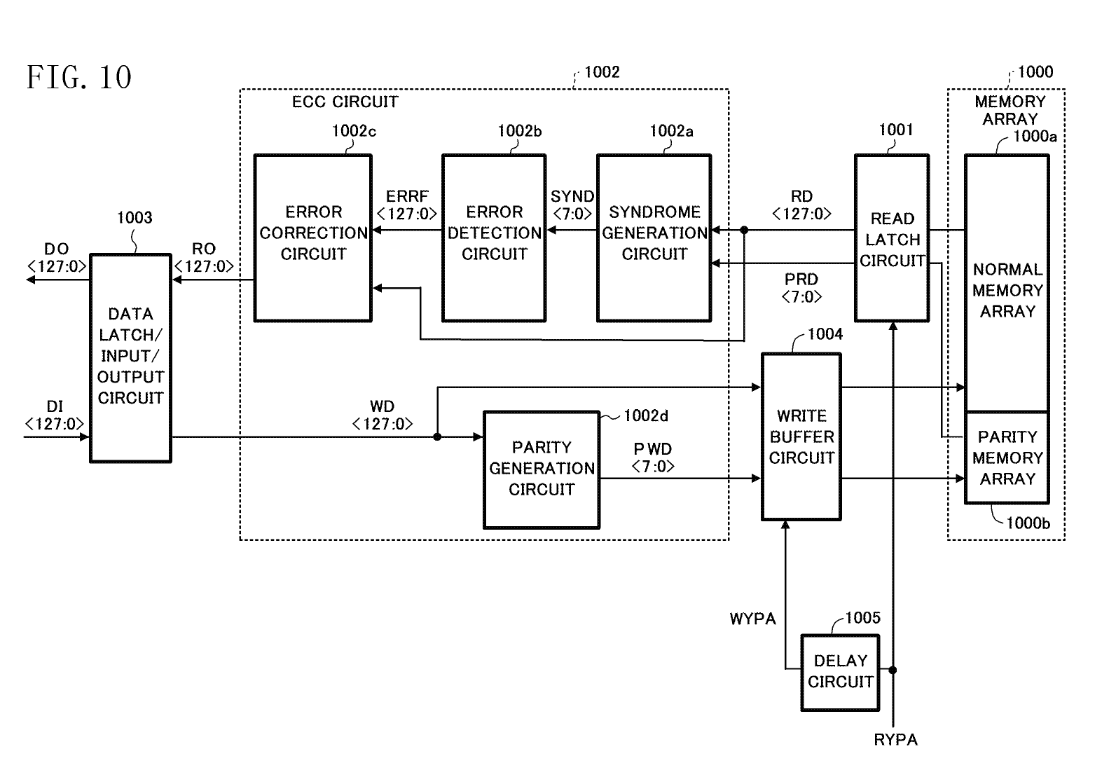

### DETAILED DESCRIPTION

Embodiments of the present disclosure will be described in detail hereinafter with reference to the accompanying drawings. Note that like parts are indicated by like reference characters throughout the specification.

### First Embodiment

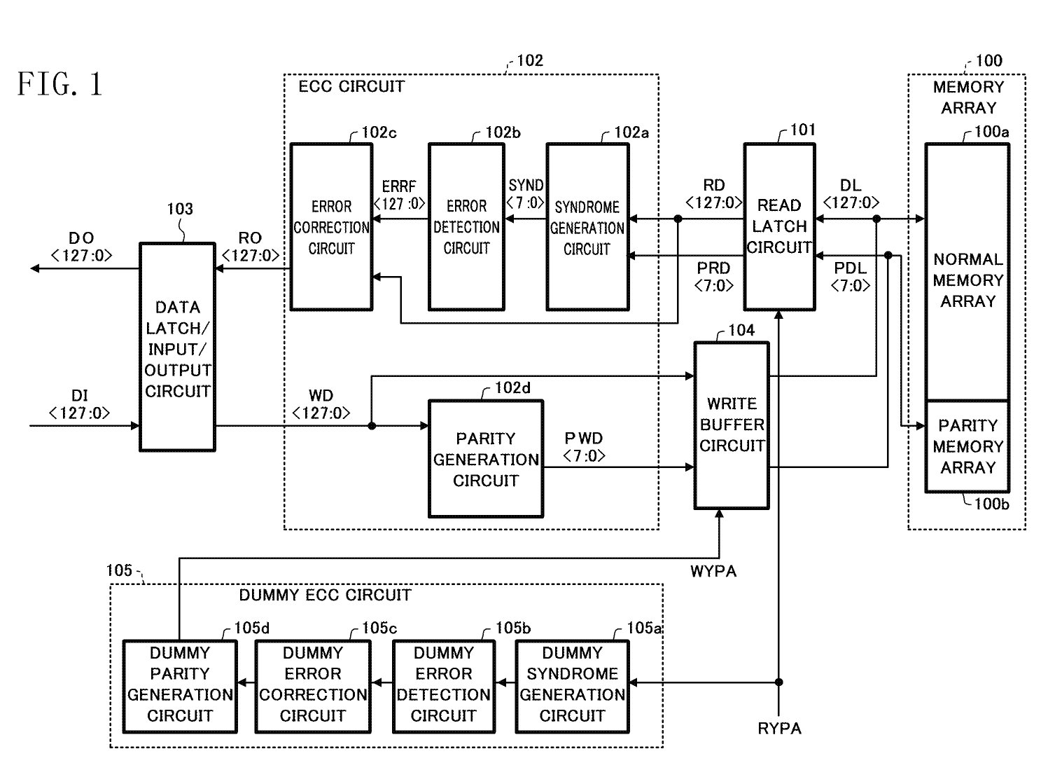

FIG. 1 is a block diagram schematically showing a configuration of a semiconductor memory device according to a first embodiment of the present disclosure including an error correction code (ECC) circuit, where the semiconductor memory device is a dynamic random access memory (DRAM). An example configuration of the semiconductor memory device including the ECC circuit will be described hereinafter in which an appropriate timing control is achieved when read-modify-write operation, which is representative operation of the semiconductor memory device including the ECC circuit, is performed.

A memory array 100 includes a normal memory array 100a for storing normal data, and a parity memory array 100b for storing test data which is used to perform error detection with respect to the normal memory array 100a. Although not shown in detail, the normal memory array 100a and the parity memory array 100b each include the same memory cells arranged in a matrix. Although not shown, data stored in each memory cell is selected by a word line which has been selected by a row decoder circuit in accordance with an externally input address signal, and read out from the memory cell into a corresponding one of a plurality of bit lines. Data read out to bit lines are sensed and amplified by sense amplifiers, and selectively read out via switch gates to a large number of normal data lines DL<127:0> and parity data lines PDL<7:0>. One sense amplifier is provided for each pair of bit lines. The sense amplifiers are arranged in one or typically a plurality of lines in the memory array 100.

As described above, data which have been read out from memory cells via bit lines to the normal data lines DL<127:0> and the parity data lines PDL<7:0> are input to a read latch circuit 101. Thereafter, a read signal RYPA is input to the read latch circuit 101, so that the data are input as normal read data RD<127:0> and parity read data PRD<7:0> to an ECC circuit 102 in the succeeding stage. Here, the ECC circuit 102 includes a syndrome generation circuit 102a, an error detection circuit 102b, an error correction circuit 102c, and a parity generation circuit 102d.

The normal read data RD<127:0> and the parity read data PRD<7:0> input to the ECC circuit 102 are initially input to the syndrome generation circuit 102a, which then generates an 8-bit syndrome SYND<7:0>. Next, the syndrome SYND<7:0> is input to the error detection circuit 102b, which then decodes the data and performs error detection to detect any error in the data bits to generate an error flag ERRF<127:0>. The error flag ERRF<127:0> is input along with the normal read data RD<127:0> to the error correction circuit 102c in the succeeding stage, which then performs error correction by reversing the data of a bit(s) having an error. The corrected read data RO<127:0> is input to and then held by a data latch/input/output circuit 103 in the succeeding stage.

Thereafter, for example, in accordance with an externally input command (not shown), a portion of the corrected read data RO<127:0> held by the data latch/input/output circuit 103 is replaced with a portion of an externally input data DI<127:0>. The resultant data is input as normal write data WD<127:0> to the parity generation circuit 102d.

The parity generation circuit 102d generates 8-bit parity write data PWD<7:0> based on the input normal write data WD<127:0>, and inputs the 8-bit parity write data PWD<7:0> along with the normal write data WD<127:0> to a write buffer circuit 104.

In the write buffer circuit 104, a buffer and another circuit including a logic element are activated in accordance with the write signal WYPA to perform write operation to write the normal write data WD<127:0> and the 8-bit parity write data PWD<7:0> to the normal memory array 100a and the parity memory array 100b, respectively.

The write signal WYPA is generated based on the same read signal RYPA as that which is input to the read latch circuit 101. Specifically, the read signal RYPA is input to a dummy ECC circuit 105 as well as the read latch circuit 101. The dummy ECC circuit 105 includes a dummy syndrome generation circuit 105a, a dummy error detection circuit 105b, a dummy error correction circuit 105c, and a dummy parity generation circuit 105d which are dummy circuits each of which has a configuration similar to that of a portion of the corresponding one of the syndrome generation circuit 102a, the error detection circuit 102b, the error correction circuit 102c, and the parity generation circuit 102d, and therefore, a similar delay. Specifically, the read signal RYPA input to the dummy ECC circuit 105 is input to the dummy syndrome generation circuit 105a, the dummy error detection circuit 105b, the dummy error correction circuit 105c, and the dummy parity generation circuit 105d successively in this stated order, i.e., the read signal RYPA passes through a path corresponding to a signal passing path in the ECC circuit 102. As a result, the read signal RYPA is input as the write signal WYPA to the write buffer circuit 104 at a timing which is delayed by a time corresponding to the time which it takes for the read signal RYPA to pass through the above path in the ECC circuit 102. Here, the delay time does not necessarily need to be exactly equal to the time which it takes for read signal RYPA to pass through the ECC circuit 102. For example, the delay time may have any time length that allows a timing control which satisfies the margin of control of the write buffer circuit 104, for example.

With the above configuration, when data is written from the write buffer circuit 104 to the memory array 100 after the read signal RYPA is input to the read latch circuit 101 and then the series of ECC processes are performed, the write signal WYPA is generated by the read signal RYPA being passed through the dummy ECC circuit 105. Therefore, the write signal WYPA which has a signal delay time and variation factors similar to those of the ECC circuit 102 can be easily produced, and therefore, an unnecessary margin of a period of time until activation of the write signal WYPA can be removed with respect to the signal delay time occurring in the ECC circuit 102. As a result, the timing of processes in the DRAM including the ECC processes can be appropriately regulated to reduce an access time, resulting in an improvement in the speed performance of the DRAM.

Although an example has been described where the semiconductor memory device of this embodiment is a DRAM, a similar advantage can be obtained even when other semiconductor memory devices (an SRAM, a flash memory, etc.) are employed.

Although, in this embodiment, an example has been described where the dummy ECC circuit 105 includes the dummy syndrome generation circuit 105a, the dummy error detection circuit 105b, the dummy error correction circuit 105c, and the dummy parity generation circuit 105d, the present disclosure is not limited to this. A similar function may be provided by a configuration which selectively includes a portion of the above circuits, a configuration which includes another circuit in addition to the above circuits, a configuration in which a portion of the above circuits is removed as long as a required timing accuracy or margin is ensured, or the like.

Note that, in this embodiment, the write signal WYPA is generated by delaying the read signal RYPA by a time corresponding to the time which it takes for the read signal RYPA to pass through the ECC circuit 102. Other logic signals, such as an inverted signal, a one-shot pulse, and the like, which are generated from the read signal RYPA may be used as the write signal WYPA. In this case, a similar advantage can be obtained.

### Second Embodiment

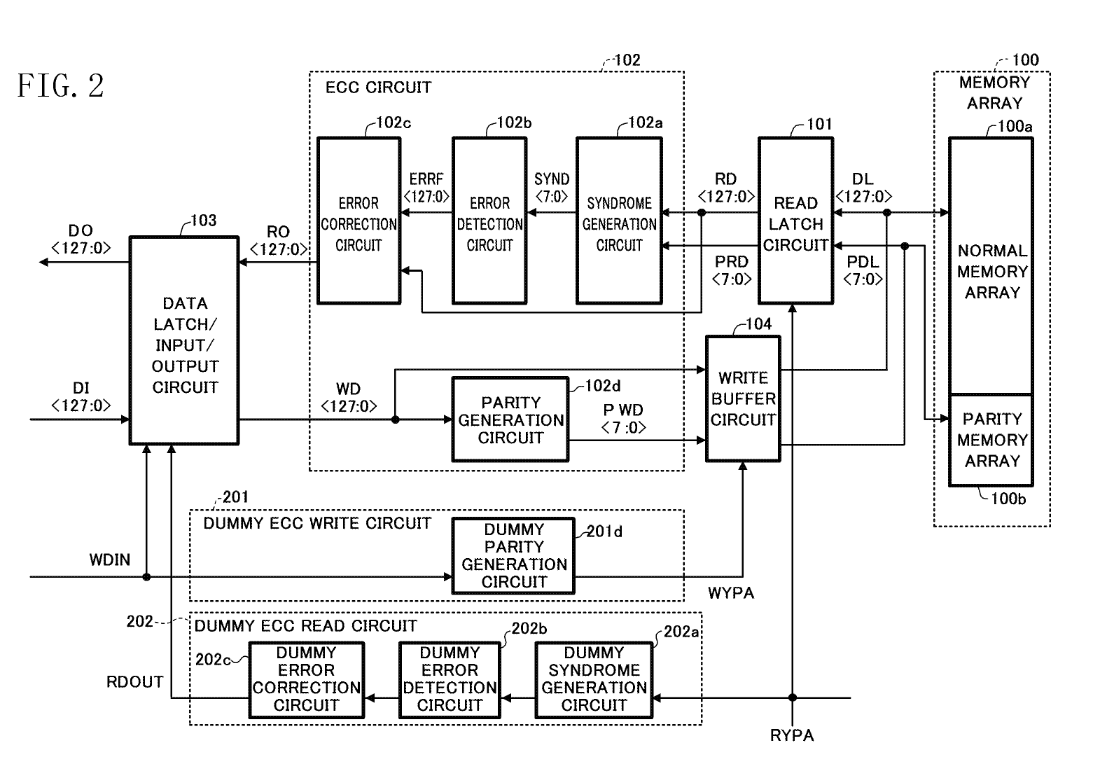

FIG. 2 is a block diagram schematically showing a configuration of a semiconductor memory device including an ECC circuit according to a second embodiment of the present disclosure, where the semiconductor memory device is a DRAM. An example configuration of the semiconductor memory device including the ECC circuit will be described hereinafter in which an appropriate timing control is achieved when write operation and read operation, which are representative operation of the semiconductor memory device including the ECC circuit, are performed.

In the write operation in the DRAM, data DI<127:0> input from the outside of the DRAM is input to the data latch/input/output circuit 103 by a control in accordance with a write data input signal WDIN, and then input as normal write data WD<127:0> to a parity generation circuit 102d. The normal write data WD<127:0> is input along with parity write data PWD<7:0> which has been generated by the parity generation circuit 102d to the write buffer circuit 104, which then writes the normal write data WD<127:0> and the parity write data PWD<7:0> to a normal memory array 100a and a parity memory array 100b, respectively, in accordance with a write signal WYPA.

The write signal WYPA is generated based on the same write data input signal WDIN as that which is input to the data latch/input/output circuit 103. In other words, the write data input signal WDIN is input to a dummy ECC write circuit 201 as well as the data latch/input/output circuit 103. The dummy ECC write circuit 201 includes a dummy parity generation circuit 201d which has a configuration similar to a portion of the parity generation circuit 102d, and therefore, a similar delay. The write data input signal WDIN input to the dummy ECC write circuit 201 is input to the dummy parity generation circuit 201d, and then input as the write signal WYPA to the write buffer circuit 104.

With the above configuration, during write operation, when the write data input signal WDIN is input to the data latch/input/output circuit 103, and the parity write data PWD<7:0> is then generated and input via the write buffer circuit 104 to the memory array 100, the write signal WYPA is generated by the write data input signal WDIN being passed through the dummy ECC write circuit 201. Therefore, the write signal WYPA which has a signal delay time and variation factors similar to those of the parity generation circuit 102d in an ECC circuit 102 can be easily produced, and therefore, an unnecessary margin of a period of time until activation of the write signal WYPA can be removed with respect to the signal delay time occurring in the ECC circuit 102. As a result, the timing of processes in the DRAM including the ECC processes can be appropriately regulated to reduce an access time, resulting in an improvement in the speed performance of the DRAM.

In the read operation in the DRAM, data read out from the normal memory array 100a and the parity memory array 100b to normal data lines DL<127:0> and parity data lines PDL<7:0> are input to a read latch circuit 101. Thereafter, a read signal RYPA is input to the read latch circuit 101, and the data are then input as normal read data RD<127:0> and parity read data PRD<7:0> to the ECC circuit 102 in the succeeding stage.

The normal read data RD<127:0> and the parity read data PRD<7:0> input to the ECC circuit 102 are initially input to the syndrome generation circuit 102a, which then generates an 8-bit syndrome SYND<7:0>. Next, the syndrome SYND<7:0> is input to an error detection circuit 102b, which then decodes the data and performs error detection to detect any error in the data bits to generate an error flag ERRF<127:0>. The error flag ERRF<127:0> and the normal read data RD<127:0> are input to an error correction circuit 102c in the succeeding stage, which then performs error correction by reversing the data of a bit(s) having an error. The corrected data is input as corrected read data RO<127:0> to a data latch/input/output circuit 103 in the succeeding stage. The corrected read data RO<127:0> is output as output data DO<127:0> via the data latch/input/output circuit 103 to the outside of the DRAM.

A read data out signal RDOUT is generated based on the same read signal RYPA as that which is input to the read latch circuit 101. Specifically, the read signal RYPA is input to a dummy ECC read circuit 202 as well as the read latch circuit 101. The dummy ECC read circuit 202 includes a dummy syndrome generation circuit 202a, a dummy error detection circuit 202b, and a dummy error correction circuit 202c which are dummy circuits each of which has a configuration similar to that of a portion of the corresponding one of the syndrome generation circuit 102a, the error detection circuit 102b, and the error correction circuit 102c, and therefore, a similar delay. The read signal RYPA input to the dummy ECC read circuit 202 is input to the dummy syndrome generation circuit 202a, the dummy error detection circuit 202b, and the dummy error correction circuit 202c successively in this stated order before being input as the read data output signal RDOUT to the data latch/input/output circuit 103.

With the above configuration, during read operation, when the output data DO<127:0> is output from the data latch/input/output circuit 103 to the outside of the DRAM after the read signal RYPA is input to the read latch circuit 101 and a series of ECC processes are then performed, the read data output signal RDOUT is generated by the read signal RYPA being passed through the dummy ECC read circuit 202. Therefore, the read data output signal RDOUT which has a signal delay time and variation factors similar to those of the syndrome generation circuit 102a, the error detection circuit 102b, and the error correction circuit 102c of the ECC circuit 102 can be easily produced, and therefore, an unnecessary margin of a period of time until activation of the read data output signal RDOUT can be removed with respect to the signal delay time occurring in the ECC circuit 102. As a result, the timing of processes in the DRAM including the ECC processes can be appropriately regulated to reduce an access time, resulting in an improvement in the speed performance of the DRAM.

Although an example has been described where the semiconductor memory device of this embodiment is a DRAM, a similar advantage can be obtained even when other semiconductor memory devices (an SRAM, a flash memory, etc.) are employed.

Although, in this embodiment, an example has been described where both the dummy ECC write circuit 201 and the dummy ECC read circuit 202 are used for read operation and write operation, the present disclosure is not limited to this. The above circuit configuration may be applied to one of read operation and write operation. In this case, a desired advantage can be obtained for each operation to which the above circuit configuration is applied.

Although, in this embodiment, an example has been described where the dummy ECC write circuit 201 includes the dummy parity generation circuit 202d, and the dummy ECC read circuit 202 include the dummy syndrome generation circuit 202a, the dummy error detection circuit 202b, and the dummy error correction circuit 202c, the present disclosure is not limited to this. A similar function may be provided by a configuration which selectively includes a portion of the above circuits, a configuration which includes another circuit in addition to the above circuits, a configuration in which a portion of the above circuits is removed as long as a required timing accuracy or margin is ensured, or the like.

### Third Embodiment

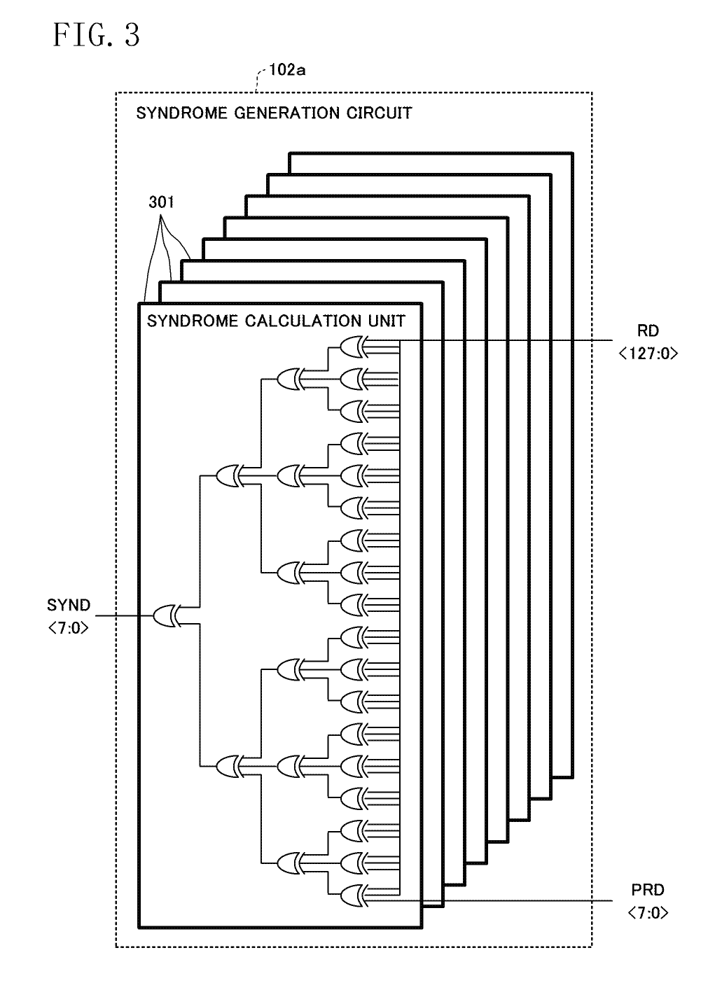

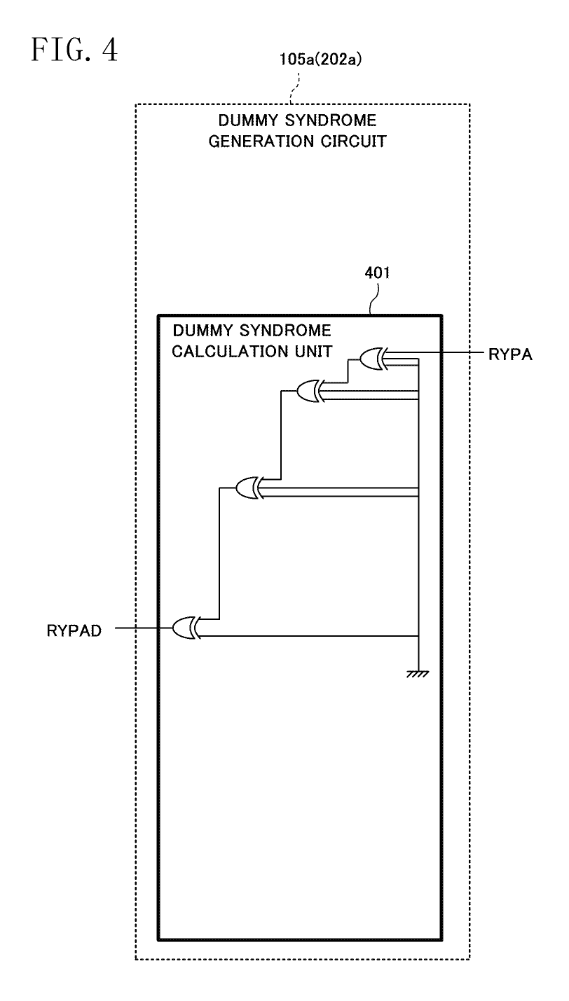

FIGS. 3 and 4 are diagrams showing details of an example circuit which can be applied to the syndrome generation circuit 102a and the dummy syndrome generation circuit 105a (202a) of the components of the semiconductor memory device including the ECC circuit of the first or second embodiment of FIG. 1 or 2. A third embodiment of the present disclosure will be described hereinafter by describing read-modify-write operation, which is representative operation of the semiconductor memory device including the ECC circuit.

Normal data and parity data stored in the memory array 100 are input via the read latch circuit 101 to the syndrome generation circuit 102a in the ECC circuit 102. As shown in FIG. 3, the normal read data RD<127:0> and the parity read data PRD<7:0> input to the syndrome generation circuit 102a are input to eight syndrome calculation units 301, which then generate the syndrome SYND<7:0> using EXOR logic elements. Thereafter, although not shown, as in the syndrome generation circuit 102a, the error detection circuit 102b, the error correction circuit 102c, and the parity generation circuit 102d receive the syndrome SYND<7:0>, the error flag ERRF<127:0>, and the normal write data WD<127:0> and output the error flag ERRF<127:0>, the corrected read data RO<127:0>, and the parity write data PWD<7:0>, respectively, via logic elements. The parity write data PWD<7:0> generated by the parity generation circuit 102d is written along the normal write data WD<127:0> via the write buffer circuit 104 to the memory array 100.

Here, as described in the first embodiment of the present disclosure, the read signal RYPA is also input to the dummy ECC circuit 105, in which the write signal WYPA is then generated by the read signal RYPA being passed through the dummy syndrome generation circuit 105a, the dummy error detection circuit 105b, the dummy error correction circuit 105c, and the dummy parity generation circuit 105d. More specifically, in the dummy ECC circuit 105, the read signal RYPA is initially input to the dummy syndrome generation circuit 105a, specifically, a dummy syndrome calculation unit 401. As shown in FIG. 4, the dummy syndrome calculation unit 401 includes the same logic elements as a portion of logic elements constituting the syndrome calculation unit 301, and outputs the input read signal RYPA as a dummy read signal RYPAD via EXOR logic elements. Compared to the syndrome calculation unit 301, the dummy syndrome calculation unit 401 includes EXOR logic elements through which the read signal RYPA and signals passed based on the read signal RYPA are passed, and excludes the other EXOR logic elements. All inputs to the EXOR logic elements constituting the dummy syndrome calculation unit 401, except for the read signal RYPA and the signals passed based on the read signal RYPA, are fixed to the low level. In the dummy syndrome calculation unit 401, the number of stages of transistors or logic elements provided on a signal path from the read signal RYPA to the dummy read signal RYPAD is the same as the number of stages of transistors or logic elements provided on a signal path from the normal read data RD<127:0> or the parity read data PRD<7:0> to the syndrome SYND<7:0> in the syndrome calculation unit 301. Note that when the number of stages varies among paths in the syndrome calculation unit 301, the number of stages in the dummy syndrome calculation unit 401 may be set to the largest number of stages in the syndrome calculation unit 301. Note that the number of stages in the dummy syndrome calculation unit 401 does not necessarily need to be equal to the largest number of stages in the syndrome calculation unit 301, and may be set to a value which substantially ensures a required timing accuracy or margin, for example.

Although not shown, as in the dummy syndrome generation circuit 105a; the dummy error detection circuit 105b, the dummy error correction circuit 105c, and the dummy parity generation circuit 105d also include the same type of logic elements and the same number of stages of transistors or logic elements as those of the error detection circuit 102b, the error correction circuit 102c, and the parity generation circuit 102d, respectively, and generate the final write signal WYPA. Note that the dummy ECC write circuits 201 and 202 of the second embodiment can also be similarly configured to generate the write signal WYPA and the read data output signal RDOUT, respectively.

With the above configuration, the write signal WYPA is generated by the read signal RYPA being passed through the dummy ECC circuit 105 including the dummy syndrome generation circuit 105a (the dummy syndrome calculation unit 401), the dummy error detection circuit 105b, the dummy error correction circuit 105c, and the dummy parity generation circuit 105d. Therefore, the write signal WYPA which has a signal delay time and variation factors similar to those of the ECC circuit 102 can be easily produced, and therefore, an unnecessary margin of a period of time until activation of the write signal WYPA can be removed with respect to the signal delay time occurring in the ECC circuit 102. As a result, the timing of processes in the DRAM including the ECC processes can be appropriately regulated to reduce an access time, resulting in an improvement in the speed performance of the DRAM.

By causing the number of stages of transistors or the like constituting the dummy ECC circuit 105 to be the same as the number of stages of transistors or the like constituting the ECC circuit 102, a signal delay on a dummy ECC signal interconnection can be caused to approach a signal delay on an ECC signal process interconnection with higher accuracy.

By causing the logic elements constituting the dummy ECC circuit 105 to be the same as those constituting the ECC circuit 102, the signal delay on the dummy ECC signal interconnection can be caused to approach the signal delay on the ECC signal process interconnection with higher accuracy as well.

By fixing all input terminals of logic elements (e.g., EXOR) constituting the dummy ECC circuit 105, except for those for the read signal RYPA and the signals passed based on the read signal RYPA, to the low level, when the level of the read signal RYPA transitions, the outputs of all the logic elements on a signal passing path transition, and the level of the dummy read signal RYPAD also invariably transitions. In other words, by all transistors on the signal passing path being switched (toggled), a signal depending on the level transition of the read signal RYPA is appropriately passed. Therefore, for example, by setting the signal passing path to correspond to the worst path in the ECC circuit 102, and setting the type of logic elements and the number of stages of transistors or logic elements to be the same as those of the ECC circuit 102, a delay in the dummy ECC circuit 105 can be easily caused to approach the longest delay in the ECC circuit 102 with high accuracy.

Although an example has been described where the semiconductor memory device of this embodiment is a DRAM, a similar advantage can be obtained even when other semiconductor memory devices (an SRAM, a flash memory, etc.) are employed.

Although, in this embodiment, an example has been described where the logic elements constituting the syndrome calculation unit 301 and the dummy syndrome calculation unit 401 are EXOR elements, the present disclosure is not limited to this. The syndrome calculation unit 301 may be any logic circuit that is configured using another type of logic elements or a combination of a plurality of types of logic elements as long as it can perform an appropriate calculation process. On the other hand, the dummy syndrome calculation unit 401 may have any configuration that has a similar function, such as a configuration which has a delay similar to that of the syndrome calculation unit 301 so that a required timing accuracy or margin can be ensured, or the like.

Although, in this embodiment, an example has been described where the logic elements constituting the dummy syndrome calculation unit 401 are the same as a portion of the logic elements constituting the syndrome calculation unit 301, the present disclosure is not limited to this. A similar function may be provided by configuring the dummy syndrome calculation unit 401 using all of the logic elements constituting the syndrome calculation unit 301.

Although, in this embodiment, an example has been described where the input terminals of the logic elements in the dummy syndrome calculation unit 401, except for those for the read signal RYPA (input signal) and signals passed based on the read signal RYPA, are fixed to the low level to generate the write signal WYPA, the present disclosure is not limited to this. A configuration having a similar function may be provided using other fixing techniques. Specifically, the input terminal may be fixed to a predetermined level, depending on the element. For example, the input terminal of an AND circuit may be fixed to the high level while the input terminal of an OR circuit may be fixed to the low level. In other words, the output of each logic element may be transitioned, depending on the level transition of an input signal to be passed, so that the signal is appropriately passed.

Although, in this embodiment, an example has been described where the number of stages of transistors or the like constituting the dummy syndrome calculation unit 401 is the same as the number of stages of transistors or the like constituting the syndrome calculation unit 301, the present disclosure is not limited to this. The number of stages of transistors or the like constituting the dummy syndrome calculation unit 401 does not need to be the same as the number of stages of transistors or the like constituting the syndrome calculation unit 301. The dummy syndrome calculation unit 401 may have any other configuration that has a function of generating the write signal WYPA or the like while ensuring a required timing accuracy or margin.

Although, in this embodiment, an example has been described where the dummy syndrome calculation unit 401 is configured using the same logic elements as those of the syndrome calculation unit 301, the present disclosure is not limited to this. Alternatively, for example, the dummy syndrome calculation unit 401 may be configured using logic elements different from those of the syndrome calculation unit 301 as long as it has a function of generating the write signal WYPA while ensuring a required timing accuracy or margin.

Although, in this embodiment, an example has been described where the number of switches of logic elements in the dummy ECC circuit 105 is the same as the number of switches of logic elements on the worst path or the like in the ECC circuit 102, the present disclosure is not limited to this. The number of switches of logic elements in the dummy ECC circuit 105 does not need to be the same as the number of switches of logic elements on the worst path or the like in the ECC circuit 102. The dummy ECC circuit 105 may have any other configuration that has a function of generating the write signal WYPA while ensuring a required timing accuracy or margin.

### Fourth Embodiment

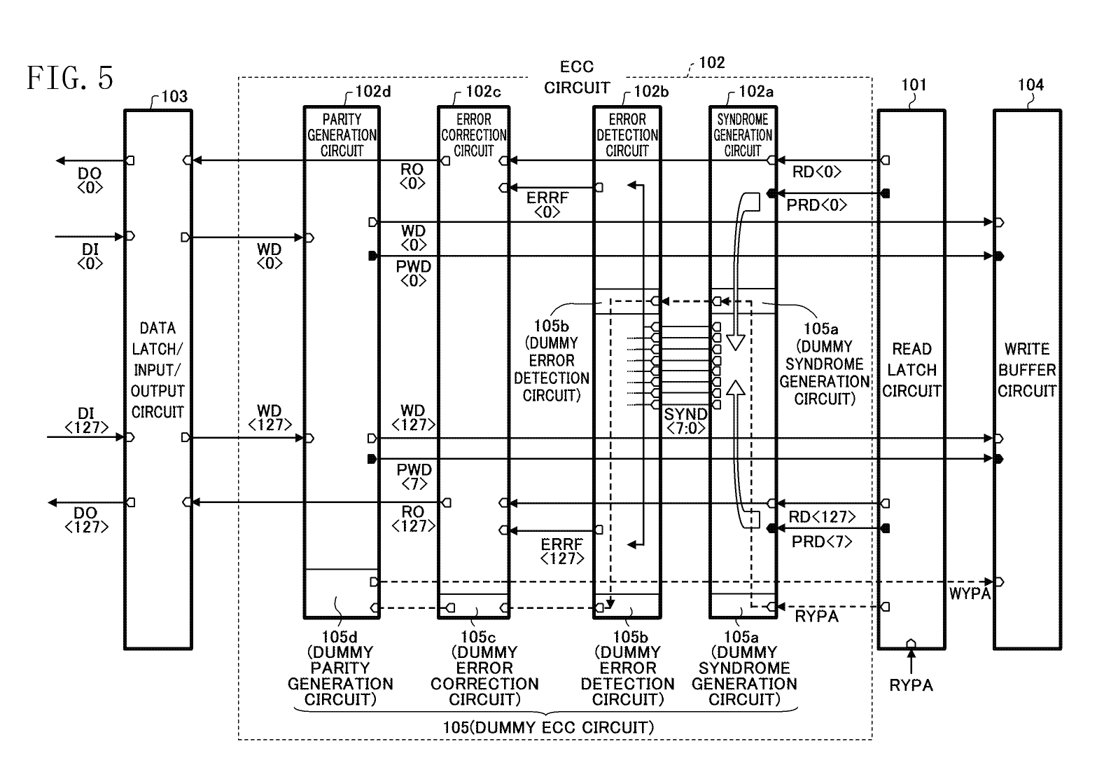

FIG. 5 is a diagram schematically showing a layout which can be applied to the semiconductor memory device including the ECC circuit according to the first embodiment of the present disclosure of FIG. 1. A fourth embodiment of the present disclosure will be described hereinafter by describing read-modify-write operation, which is representative operation of the semiconductor memory device including the ECC circuit.

As in the first embodiment, normal data and parity data input from a memory array 100 (not shown) to a read latch circuit 101 is written via a syndrome generation circuit 102a, an error detection circuit 102b, an error correction circuit 102c, a data latch/input/output circuit 103, a parity generation circuit 102d, and a write buffer circuit 104 back to the memory array 100. A dummy ECC circuit 105 which generates a write signal WYPA based on a read signal RYPA includes, as shown in FIG. 5, a dummy syndrome generation circuit 105a, a dummy error detection circuit 105b, a dummy error correction circuit 105c, and a dummy parity generation circuit 105d.

As described above, in a typical layout, an ECC circuit block is provided between a memory array and an input/output circuit, likely leading to a problem that the aspect ratio of the block is large, in other words, the ratio of the length to the width of a block is large. In addition, for the signal interconnections involved with the ECC processes, the number of input terminals is different from the number of output terminals in each element block, such as the syndrome generation circuit 102a or the error detection circuit 102b (in this example, 8:128). Therefore, of the signal interconnections involved with the ECC processes, there is an interconnection which extends back and forth in the same direction to connect logic elements in the ECC circuit 102, and therefore, has a long distance. In addition, as described above, the recent advance in device microfabrication technology is accompanied by a tendency toward higher and higher interconnection resistance. Therefore, there is inevitably a large interconnection delay due to interconnection resistance, parasitic capacitance between interconnections, and the like, in addition to a transistor delay in circuit devices. In this case, even when the write signal WYPA is generated by the dummy ECC circuit 105, then if the dummy syndrome generation circuit 105a, the dummy error detection circuit 105b, the dummy error correction circuit 105c, and the dummy parity generation circuit 105d constituting the dummy ECC circuit 105 are arranged adjacent to each other with a distance between each circuit being minimized, the delay in the dummy ECC signal interconnection, particularly the signal interconnection delay due to interconnection parasitic resistance or parasitic capacitance between interconnections, is extremely smaller than the aforementioned signal interconnection delay in the ECC process signal path. Therefore, the original purpose of using the dummy ECC circuit 105 to generate a dummy ECC signal interconnection having a delay amount similar to that of the ECC signal interconnection may not be sufficiently achieved.

In such a case, it is preferable that, for example, as shown in FIG. 5, a portion of the circuits constituting the dummy ECC circuit 105 be distributed and provided in the region of the ECC circuit 102. Specifically, the dummy syndrome generation circuit 105a and the dummy error detection circuit 105b are each divided into two blocks, which are distributed and provided in the region of the syndrome generation circuit 102a or the error detection circuit 102b, respectively. More specifically, the two blocks are distributed and provided at two portions, i.e., a center portion and an end portion, of the region of the syndrome generation circuit 102a or the error detection circuit 102b. Interconnections connecting the dummy syndrome generation circuit 105a and the like include, for example, an interconnection which extends back and forth in at least one of a horizontal direction and a vertical direction as shown in FIG. 5.

With the above configuration, in the syndrome generation circuit 102a and the error detection circuit 102b, which are highly likely to require a long-distance interconnection which extends back and forth in the same direction and serves as an ECC process signal path, a dummy ECC signal interconnection which has an interconnection length similar to the maximum interconnection length of the ECC process signal interconnections can be easily provided in the dummy syndrome generation circuit 105a and the dummy error detection circuit 105b, and therefore, a configuration can be easily provided in which the ECC signal interconnection and the dummy ECC signal interconnection have similar interconnection lengths and similar interconnection delay amounts. As a result, for an interconnection delay due to interconnection parasitic resistance or parasitic capacitance between interconnections as well as a transistor delay which causes a signal interconnection delay, the ECC signal interconnection and the dummy ECC signal interconnection are easily allowed to have similar delay amounts, whereby the timing accuracy of the dummy ECC signal interconnection can be easily further improved.

The dummy ECC signal interconnection may have an interconnection layout pattern similar to that of the ECC signal interconnection. Specifically, for example, both of the interconnections may have similar line widths or similar intervals between the interconnection and another interconnection or may be formed of the same interconnection layer. In this case, the ECC signal interconnection and the dummy ECC signal interconnection can have more similar signal interconnection delays.

Although an example has been described where the semiconductor memory device of this embodiment is a DRAM, a similar advantage can be obtained even when other semiconductor memory devices (an SRAM, a flash memory, etc.) are employed.

Although, in this embodiment, an example has been described where the dummy syndrome generation circuit 105a and the dummy error detection circuit 105b are each divided into two blocks, which are then distributed and provided, the present disclosure is not limited to this. Alternatively, the logic elements constituting the dummy syndrome generation circuit 105a and the dummy error detection circuit 105b may be integrated into a single block without being distributed and provided in two blocks, and the dummy ECC signal interconnection may set to have a distance similar to that of the ECC signal interconnection in the block. Alternatively, the dummy syndrome generation circuit 105a and the dummy error detection circuit 105b may be each divided into three or more blocks, which are then distributed and provided. The dummy syndrome generation circuit 105a and the dummy error detection circuit 105b may have any other configuration that has a similar function of generating the write signal WYPA or the like while ensuring a required timing accuracy or margin.

Although, in this embodiment, an example has been described where the dummy syndrome generation circuit 105a and the dummy error detection circuit 105b are each distributed and provided at two portions, i.e., a center portion and an end portion, of the region of the syndrome generation circuit 102a or the error detection circuit 102b, respectively, the present disclosure is not limited to this. Alternatively, the dummy syndrome generation circuit 105a and the dummy error detection circuit 105b may be each distributed and provided at portions other than the above portions or at three or more portions. The dummy syndrome generation circuit 105a and the dummy error detection circuit 105b may have any other configuration that has a similar function of generating the write signal WYPA or the like while ensuring a required timing accuracy or margin.

Although, in this embodiment, an example has been described where the dummy syndrome generation circuit 105a and the dummy error detection circuit 105b are each distributed and provided, the present disclosure is not limited to this. In addition to the dummy syndrome generation circuit 105a and the dummy error detection circuit 105b, other circuits, i.e., the dummy error correction circuit 105c or the dummy parity generation circuit 105d, may be distributed and provided. Alternatively, only the dummy syndrome generation circuit 105a or the dummy error detection circuit 105b may be distributed and provided.

Any other configuration may be employed if it has a function of generating the write signal WYPA or the like while ensuring a required timing accuracy or margin.

### Fifth Embodiment

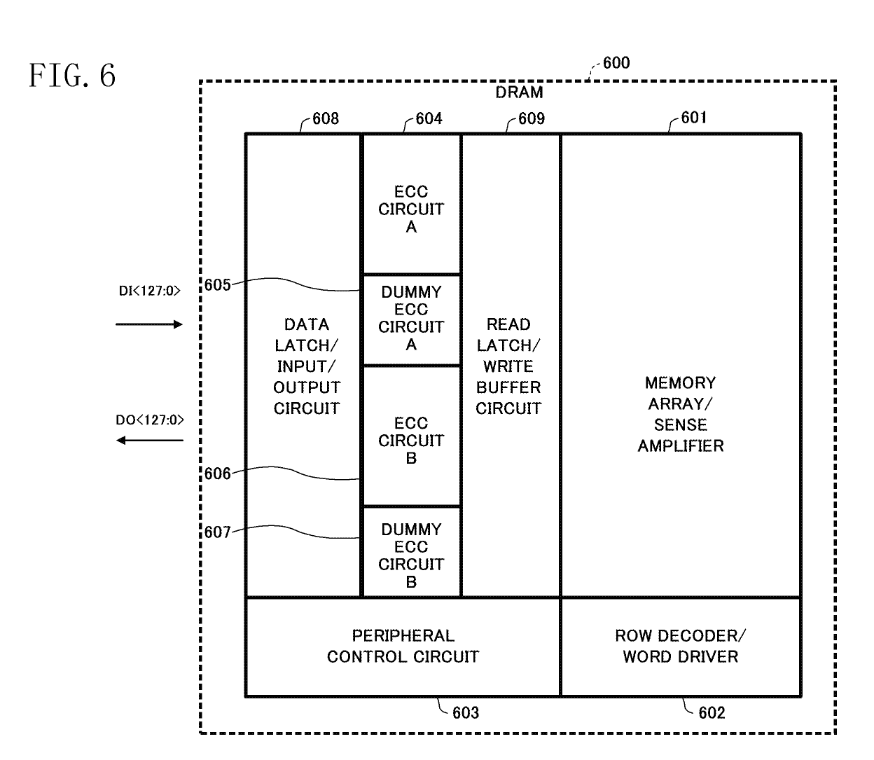

FIG. 6 is a diagram schematically showing a layout of a semiconductor memory device including an ECC circuit according to a fifth embodiment of the present disclosure.

In the semiconductor memory device of the first embodiment, the write signal WYPA for controlling the write buffer circuit 104, or the like, is a single signal common to data of all bits which are to be written to the memory array 100. The present disclosure is not limited to this. Alternatively, all bits may be divided into a plurality of groups, and the write signal WYPA or the like may be generated for each group. Specifically, for example, if the dummy ECC circuit 105 is provided for each of circuit blocks corresponding to respective groups in the ECC circuit 102, then even when a delay time varies from circuit block to circuit block, timing can be easily appropriately controlled for each circuit block. Moreover, if each circuit block in the ECC circuit 102 is provided adjacent to the corresponding dummy ECC circuit 105, timing can be controlled, depending on variations in a characteristic of a circuit formed in each region of the semiconductor substrate.

Similarly, a plurality of the dummy ECC circuits 105 may be provided, and the write buffer circuit 104 or the like may be controlled using, for example, the latest timing of the write signals WYPA or the like generated by the dummy ECC circuits 105. This will be specifically described hereinafter.

As shown in FIG. 6, a DRAM 600 includes a memory array/sense amplifier 601, a row decoder/word driver 602, a peripheral control circuit 603, an ECC circuit A604, a dummy ECC circuit A605, an ECC circuit B606, a dummy ECC circuit B607, a data latch/input/output circuit 608, and a read latch/write buffer circuit 609. The ECC circuit A604 and the ECC circuit B606 arranged as shown in FIG. 6 constitute an ECC circuit. Similarly, the dummy ECC circuits A605 and B607 constitute a dummy ECC circuit.

With the above configuration, the ECC circuit A604 and the dummy ECC circuit A605 are paired and the ECC circuit B606 and the dummy ECC circuit B607 are paired so that portions corresponding to the ECC circuit A604 and the ECC circuit B606 of the data latch/input/output circuit 608 or the read latch/write buffer circuit 609 are separately controlled using dummy ECC signals generated by the dummy ECC circuits A605 and B607. As a result, even when the signal interconnection delay of the ECC signal varies among blocks in the same DRAM macro, the dummy ECC signal can be appropriately controlled for each block, whereby the overall timing of the DRAM macro can be appropriately regulated.

Alternatively, a single dummy ECC signal is generated from the dummy ECC signals generated by the dummy ECC circuits A605 and B607, using a logic element. Specifically, for example, when the dummy ECC signals are active high, a single dummy ECC signal is generated using an AND logic element. By thus controlling the data latch/input/output circuit 608 or the read latch/write buffer circuit 609 using a single dummy ECC signal for the entire DRAM macro, the entire DRAM can be controlled, taking into consideration variations in the ECC signal interconnection and the dummy ECC signal interconnection among the blocks, whereby the overall timing of the DRAM macro can be appropriately regulated.

Although an example has been described where the semiconductor memory device of this embodiment is a DRAM, a similar advantage can be obtained even when other semiconductor memory devices (an SRAM, a flash memory, etc.) are employed.

Although, in this embodiment, an example has been described where an ECC circuit and a dummy ECC circuit are each provided in two blocks in a single DRAM macro, the present disclosure is not limited to this. Alternatively, three or more dummy ECC circuits may be provided in a single DRAM macro, or the ECC circuit and the dummy ECC circuit may be provided along with other blocks on opposite sides in the vertical direction of FIG. 6 of the peripheral control circuit 603 and the row decoder/word driver 602 so that the ECC circuit and the dummy ECC circuit and other blocks sandwich the peripheral control circuit 603 and the row decoder/word driver 602 in the vertical direction. Any other configuration may be employed if it has a function of generating the write signal WYPA or the like while ensuring a required timing accuracy or margin.

Although, in this embodiment, an example has been described where an ECC circuit and a dummy ECC circuit are each provided in two blocks in a single DRAM macro, the present disclosure is not limited to this. Alternatively, two or more dummy ECC circuits may be provided for a single ECC circuit, or a single dummy ECC circuit may be provided for two or more ECC circuits. Any other configuration may be employed if it has a function of generating the write signal WYPA or the like while ensuring a required timing accuracy or margin.

### Sixth Embodiment

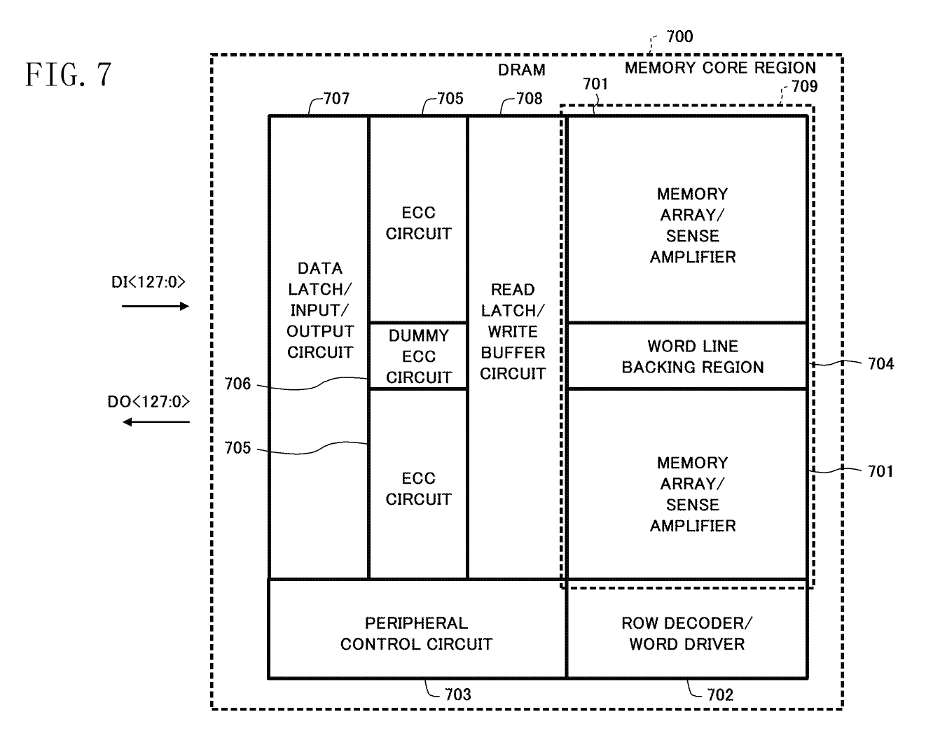

For example, the circuit components of the first embodiment may be laid out as shown in FIG. 7.

FIG. 7 is a diagram schematically showing a layout of a semiconductor memory device including an ECC circuit according to a sixth embodiment of the present disclosure.

A DRAM 700 includes memory array/sense amplifiers 701, a row decoder/word driver 702, a peripheral control circuit 703, a word line backing region 704, ECC circuits 705, a dummy ECC circuit 706, a data latch/input/output circuit 707, and a read latch/write buffer circuit 708. The word line backing region 704 is provided between the memory array/sense amplifiers 701, and the dummy ECC circuit 706 is provided between the ECC circuits 705. The word line backing region 704 is a region for providing connection contacts between backing word lines (not shown) for reducing the interconnection resistances of word lines (not shown) provided in the memory array/sense amplifiers 701, and the word lines. A memory core region 709 includes the memory array/sense amplifier 701 and the word line backing region 704.

With the above configuration, the data latch/input/output circuit 707 or the read latch/write buffer circuit 708 is controlled using a dummy ECC signal generated by the dummy ECC circuit 706, and the dummy ECC circuit 706 is provided in a region corresponding to the word line backing region 704 of the memory core region 709. Because such a region corresponds to an empty region of a typical layout in which an element is not provided, the dummy ECC circuit 706 can be provided without increasing the area of the DRAM macro. Therefore, the improvement in the speed performance of the DRAM caused by appropriate timing and the reduction in the area of the DRAM macro can be simultaneously achieved.

Although an example has been described where the semiconductor memory device of this embodiment is a DRAM, a similar advantage can be obtained even when other semiconductor memory devices (an SRAM, a flash memory, etc.) are employed.

Although, in this embodiment, an example has been described where a single dummy ECC circuit 706 and a single word line backing region 704 are provided in the DRAM macro, the present disclosure is not limited to this. Alternatively, a plurality of dummy ECC circuits 706 and a plurality of word line backing regions 704 may be provided in a single DRAM macro. Any other configuration may be employed if it has a similar function of generating the write signal WYPA or the like while ensuring a required timing accuracy or margin.

### Seventh Embodiment

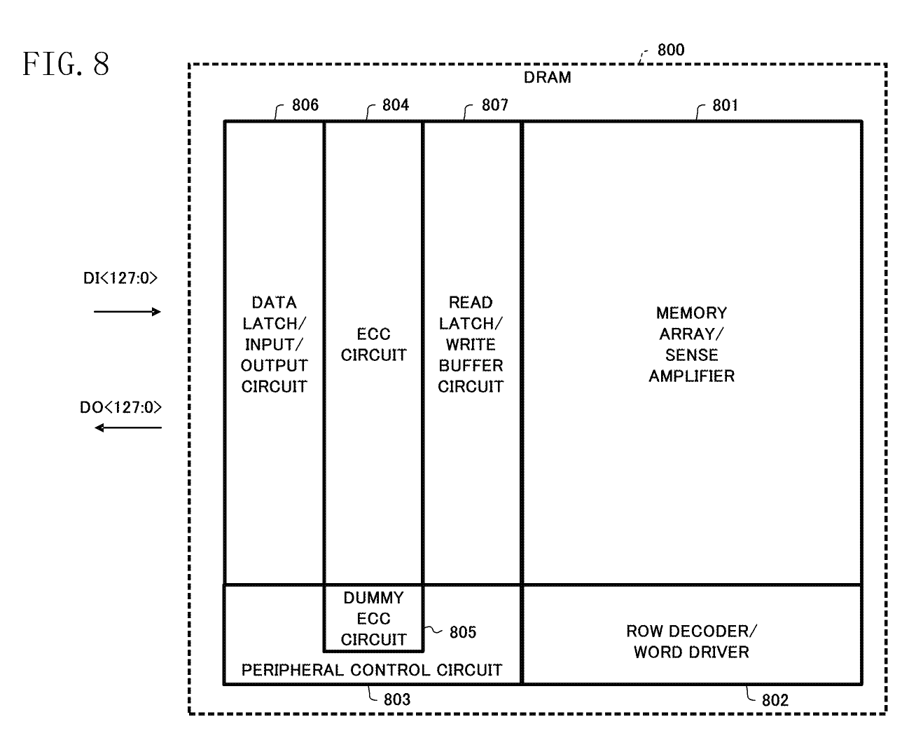

For example, the circuit components of the first embodiment may be laid out as shown in FIG. 8.

FIG. 8 is a diagram schematically showing a layout of a semiconductor memory device including an ECC circuit according to a seventh embodiment of the present disclosure.

A DRAM 800 includes a memory array/sense amplifier 801, a row decoder/word driver 802, a peripheral control circuit 803, an ECC circuit 804, a dummy ECC circuit 805, a data latch/input/output circuit 806, and a read latch/write buffer circuit 807. The dummy ECC circuit 805 is provided in the peripheral control circuit 803 and adjacent to the ECC circuit 804.

With the above configuration, the data latch/input/output circuit 806 or the read latch/write buffer circuit 807 is controlled using a dummy ECC signal generated by the dummy ECC circuit 805, and the dummy ECC circuit 805 is provided in the region of the peripheral control circuit 803. Therefore, even if the dummy ECC circuit 805 cannot be provided in the ECC circuit 804, the dummy ECC circuit 805 can be incorporated by, for example, minimizing an increase in the area of the DRAM macro, and the dummy ECC signal can be supplied to one of the data latch/input/output circuit 806 and the read latch/write buffer circuit 807 without a significant interconnection loss. As a result, the improvement in the speed performance of the DRAM caused by appropriate timing and the reduction in the area of the DRAM macro can be simultaneously achieved.

Although an example has been described where the semiconductor memory device of this embodiment is a DRAM, a similar advantage can be obtained even when other semiconductor memory devices (an SRAM, a flash memory, etc.) are employed.

Although, in this embodiment, an example has been described where the dummy ECC circuit 805 is provided in the region of the peripheral control circuit 803, the present disclosure is not limited to this. Alternatively, the dummy ECC circuit 805 may be provided in the data latch/input/output circuit 806, the read latch/write buffer circuit 807, or other circuit blocks. Any other configuration may be employed if it has a similar function of generating, for example, the write signal WYPA having a signal delay caused by a signal interconnection distance or the like while ensuring a required timing accuracy or margin.

Although, in this embodiment, an example has been described where the dummy ECC circuit 805 is provided in the region of the peripheral control circuit 803, the present disclosure is not limited to this. Alternatively, the dummy ECC circuit 805 may be provided adjacent to a block, such as the peripheral control circuit 803, the ECC circuit 804, the data latch/input/output circuit 806, the read latch/write buffer circuit 807, or the like. Any other configuration may be employed if it has a similar function of generating the write signal WYPA or the like while ensuring a required timing accuracy or margin.

### Eighth Embodiment

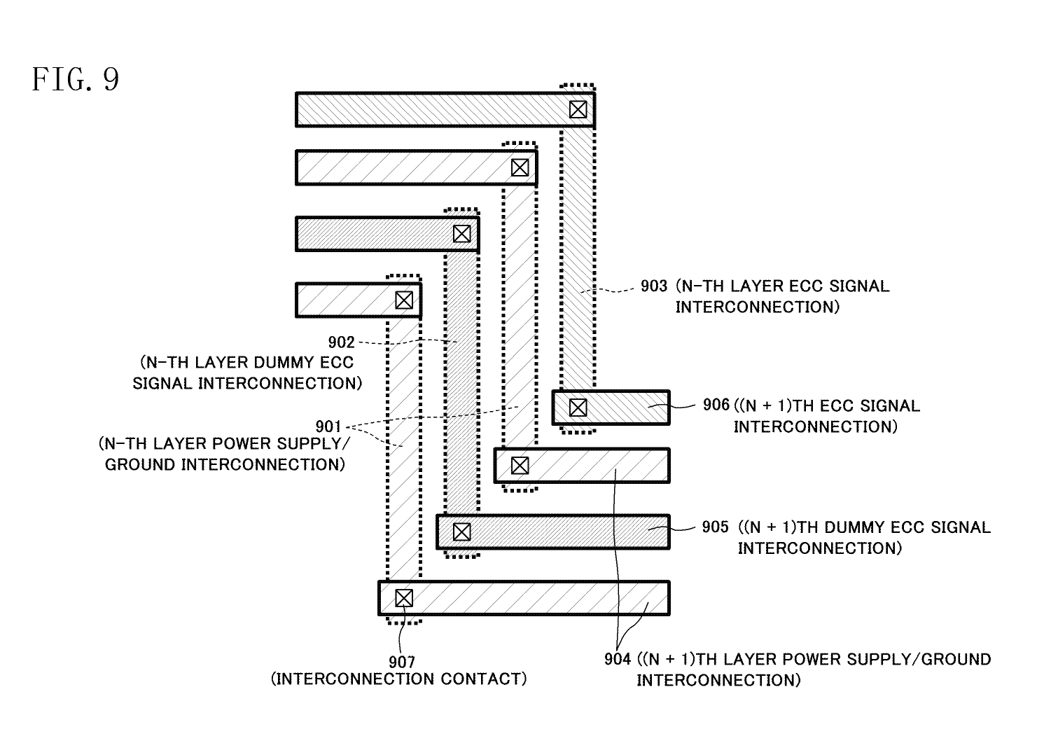

For example, the circuit components of the first embodiment may be laid out as shown in FIG. 9.

FIG. 9 is a diagram schematically showing an interconnect layout of a semiconductor memory device including an ECC circuit according to an eighth embodiment of the present disclosure.

A power supply/ground interconnection includes an n-th layer power supply/ground interconnection 901 and an (n+1)th layer power supply/ground interconnection 904. A signal interconnection for a dummy ECC circuit includes an n-th layer dummy ECC signal interconnection 902 and an (n+1)th layer dummy ECC signal interconnection 905. A signal interconnection for the ECC circuit includes an n-th layer ECC signal interconnection 903 and an (n+1)th layer ECC signal interconnection 906. The n-th layer interconnections and the (n+1)th layer interconnections are connected via interconnection contacts 907. The n-th layer power supply/ground interconnection 901 and the (n+1)th layer power supply/ground interconnection 904 are provided between the n-th layer dummy ECC signal interconnection 902 and the (n+1)th layer dummy ECC signal interconnection 905, and the n-th layer ECC signal interconnection 903 and the (n+1)th layer ECC signal interconnection 906.

With the above configuration, a shield interconnection is provided between the signal interconnection for the dummy ECC circuit and the signal interconnection for the ECC circuit, whereby noise interference between these signal interconnections can be reduced or prevented, resulting in an improvement in the stability of operation of the DRAM.

Moreover, the ECC circuit region and the dummy ECC circuit region can provide enough power supply interconnections and ground interconnections, whereby a power supply voltage can be stably supplied to the DRAM macro, and therefore, a voltage drop can be reduced or prevented, resulting in an improvement in the stability of operation of the DRAM.

Although, in this embodiment, an example has been described where a single type of power supply or ground interconnection is provided between the signal interconnection for the dummy ECC circuit and the signal interconnection for the ECC circuit, the present disclosure is not limited to this. Alternatively, a plurality of the same power supply or ground interconnections, or a plurality of types of power supply or ground interconnections, may be provided. Any other configuration may be employed if it has a similar function.

Although, in this embodiment, an example has been described where two interconnection layers, i.e., n-th layer and (n+1)th layer interconnections, constitute a shield configuration, the present disclosure is not limited to this. Alternatively, a single interconnection layer or three or more interconnection layers may constitute a shield. Any other configuration may be employed if it has a similar function.

Note that the components described in the above embodiments and variations may be combined in various manners as long as the combination is logically appropriate. Specifically, for example, the configurations of the fourth to eighth embodiments may be applied to the configuration of the second embodiment.

As described above, the ECC circuit technique of the present disclosure can ensure a sufficient yield and reliability without providing a column redundancy replacement function, and can easily reduce or prevent an increase in chip area, for example. More specifically, for example, the semiconductor memory device of the present disclosure including an ECC circuit and having a self-correction function can improve the speed performance of access including the ECC process operation. In addition, the semiconductor memory device of the present disclosure has a layout of a dummy ECC circuit which simultaneously achieves a reduction in chip area and a higher speed, and easily improve a yield and reliability.

The semiconductor memory device of the present disclosure has an advantage of reducing the decrease in the operating speed performance caused by incorporation of the ECC function, and is particularly useful as, for example, a semiconductor memory device including an error correction code (ECC) circuit.

What is claimed is:

1. A semiconductor memory device comprising:
a memory array including a normal memory array configured to store normal data and a code memory array configured to store error detection/correction code data used to perform error detection/correction with respect to the normal data;
an error correction code circuit including a code generator configured to generate the error detection/correction code data based on the normal data to be written to the normal memory array, and an error detector/corrector configured to, based on the normal data and the error detection/correction code data read out from the memory array, perform error detection/correction with respect to the normal data; and
a timing control signal generator configured to, based on a first timing control signal used to control a timing at which data to be input to the error correction code circuit is transferred to the error correction code circuit, generate a second timing control signal used to control a timing at which data output from the error correction code circuit is transferred from the error correction code circuit to another circuit,
wherein
the timing control signal generator includes a circuit which is the same as or corresponds to at least a portion of the error correction code circuit, and is configured to delay a timing of the first timing control signal by a period of time corresponding to a delay time of the error correction code circuit, and output the second timing control signal, depending on the delayed timing of the first timing control signal.

2. The semiconductor memory device of claim 1, wherein
modified normal data including at least a portion of data which has been subjected to the error detection/correction by the error detector/corrector based on the normal data and the error detection/correction code data read out from the memory array, and at least a portion of data which has been input from the outside of the semiconductor memory device, and error detection/correction code data generated by the code generator based on the second normal data, are written to the memory array,
the first timing control signal is a signal used to control a timing at which the normal data and the error detection/correction code data read out from the memory array are transferred to the error detector/corrector,
the second timing control signal is a signal used to control a timing at which the modified normal data and the error detection/correction code data to be written to the memory array is transferred to the memory array, and
the timing control signal generator includes a circuit which is the same as or corresponds to at least a portion of a circuit or circuits constituting the error detector/corrector and the code generator, and is configured to delay a timing of the first timing control signal by a period of time corresponding to a delay time of the error detector/corrector and the code generator, and output the second timing control signal, depending on the delayed timing of the first timing control signal.

3. The semiconductor memory device of claim 1, wherein
the first timing control signal is a signal used to control a timing at which the normal data and the error detection/correction code data read out from the memory array are transferred to the error detector/corrector,
the second timing control signal is a signal used to control a timing at which data subjected to the error detection/correction by the error detector/corrector is transferred to a circuit external to the semiconductor memory device, and
the timing control signal generator includes a circuit which is the same as or corresponds to at least a portion of a circuit or circuits constituting the error detector/corrector, and is configured to delay a timing of the first timing control signal by a period of time corresponding to a delay time of the error detector/corrector, and output the second timing control signal, depending on the delayed timing of the first timing control signal.

4. The semiconductor memory device of claim 1, wherein
the first timing control signal is a signal used to control a timing at which the normal data which has been input from the outside of the semiconductor memory device and is to be written to the memory array is transferred to the code generator,
the second timing control signal is a signal used to control a timing at which the normal data to be written to the memory array, and the error detection/correction code data generated by the code generator based on the normal data, are transferred to the memory array, and
the timing control signal generator includes a circuit which is the same as or corresponds to at least a portion of a circuit or circuits constituting the code generator, and is configured to delay a timing of the first timing control signal by a period of time corresponding to a delay time of the code generator, and output the second timing control signal, depending on the delayed timing of the first timing control signal.

5. The semiconductor memory device of claim 1, wherein
the timing control signal generator includes, on a signal path between the first and second timing control signals, the same number of stages of transistors as the number of stages of transistors provided between an input signal and an output signal of the error correction code circuit.

6. The semiconductor memory device of claim 1, wherein
the timing control signal generator includes, on a signal path between the first and second timing control signals, a logic element corresponding to a logic element provided between an input signal and an output signal of the error correction code circuit.

7. The semiconductor memory device of claim 6, wherein
the logic element includes a logic element configured to receive an input signal to be passed and one or more other signals, and the one or more other signals are maintained at a level which allows an output of the logic element to transition, depending on level transition of the input signal to be passed.

8. The semiconductor memory device of claim 1, wherein
the number of toggles of transistors provided on a signal path between the first and second timing control signals in the timing control signal generator is the same as the number of toggles of transistors provided between an input signal and an output signal of the error correction code circuit.

9. The semiconductor memory device of claim 1, wherein
in the timing control signal generator, all transistor or transistors provided on a signal path between the first and second timing control signals are toggled, depending on level transition of the first timing control signal.

10. The semiconductor memory device of claim 1, wherein
the error correction code circuit and the timing control signal generator are configured to have an equal sum of a transistor delay caused by a signal passing through a transistor or transistors and an interconnection delay caused by interconnection parasitic resistance, and parasitic capacitance between interconnections, of a signal interconnection.

11. The semiconductor memory device of claim 1, wherein
the timing control signal generator includes, on a signal path between the first and second timing control signals, a signal interconnection having a layout corresponding to a signal interconnection between an input signal and an output signal of the error correction code circuit.

12. The semiconductor memory device of claim 1, wherein
the timing control signal generator includes, on a signal path between the first and second timing control signals, a signal interconnection extending back and forth in at least one of two orthogonal directions of an interconnection pattern constituting a signal path from a position of a circuit arrangement of the error correction code circuit where the normal data read out from the memory array, or the normal data which has been input from the outside of the semiconductor memory device and is to be written to the memory array, is input, to a position of the circuit arrangement where data which has been subjected to the error detection/correction, or the error detection/correction code data, is output.

13. The semiconductor memory device of claim 1, wherein
data bits input to or output from the memory array are divided into a plurality of groups, the timing control signal generator is provided for each of the groups, and a data transfer timing corresponding to each of the groups is controlled based on the second timing control signal generated by the corresponding timing control signal generator.

14. The semiconductor memory device of claim 1, wherein
the timing control signal generator includes a plurality of basic timing control signal generators each including a circuit which is the same as or corresponds to at least a portion of a circuit or circuits constituting the error correction code circuit, and configured to delay a timing of the first timing control signal by a period of time corresponding to a delay time of the error correction code circuit, and generate a third timing control signal, depending on the delayed timing of the first timing control signal, and
of the plurality of third timing control signals output from the plurality of basic timing control signal generators, one corresponding to a predetermined timing is output as the second timing control signal.

15. The semiconductor memory device of claim 14, wherein
of the plurality of third timing control signals, one corresponding to a most delayed timing is output as the second timing control signal.

16. The semiconductor memory device of claim 1, wherein
the timing control signal generator is formed in a first region in which at least one of an input/output circuit unit configured to control input/output of data between the error correction code circuit and the outside of the semiconductor memory device, and a peripheral logic circuit unit configured to generate a control signal for each unit of the semiconductor memory device, or in a second region adjacent to the first region.

17. The semiconductor memory device of claim 1, wherein
at least a portion of an interconnection or interconnections constituting the error correction code circuit and at least a portion of an interconnection or interconnections constituting the timing control signal generator are provided with one or more other interconnections being interposed therebetween.
